(19) United States
(12) Patent Application Publication
(10) Pub. No.: US 2026/0265917 A1
(43) Pub. Date: Sep. 10, 2026

(54) INJECTION FLANGE ASSEMBLIES, SEMICONDUCTOR PROCESSING SYSTEMS, AND CHAMBER ARRANGEMENTS INCLUDING INJECTION FLANGE ASSEMBLIES, AND RELATED METHODS OF MAKING INJECTION FLANGE ASSEMBLIES AND CONTROLLING FLUID FLOW

(71) Applicant: ASM IP Holding B.V., Almere (NL)

(72) Inventors: Chuwei Chen, Tempe, AZ (US); Wentao Wang, Chandler, AZ (US); Junwei Su, Chandler, AZ (US); Shujin Huang, Phoenix, AZ (US); William McCullough, Mesa, AZ (US); Bradley Wayne Evans, Apache Junction, AZ (US)

(21) Appl. No.: 19/557,501

(22) Filed: Mar. 5, 2026

Related U.S. Application Data
(60) Provisional application No. 63/769,464, filed on Mar. 10, 2025.

(51) Int. Cl. C23C 16/455; C23C 16/458; C23C 16/52; H10P 72/00

(52) U.S. Cl. CPC C23C 16/45591; C23C 16/4584; C23C 16/52; H10P 72/0402

(57) ABSTRACT

An injection flange assembly includes a flange body with a first face having a recess and a second face separated by a thickness. A lateral slit extends through the thickness to couple the faces. A fluid channel within the thickness fluidly couples the recess to an edge of the flange body, the edge coupling the first and second faces. First and second threaded apertures are defined in the first face, with the first aperture separating the edge from the second aperture, and the second aperture separating the first aperture from the recess. The recess fluidly couples the fluid channel to the lateral slit. Semiconductor processing systems and chamber arrangements including the injection flange assembly, methods of making the assembly, and flow control methods are also described.

### CROSS-REFERENCE TO RELATED APPLICATIONS

This application is a nonprovisional of, and claims priority to and the benefit of, U.S. Provisional Patent Application No. 63/769,464, filed Mar. 10, 2025 and entitled “INJECTION FLANGE ASSEMBLIES, SEMICONDUCTOR PROCESSING SYSTEMS AND CHAMBER ARRANGEMENTS INCLUDING INJECTION FLANGE ASSEMBLIES, AND RELATED METHODS OF MAKING INJECTION FLANGE ASSEMBLIES AND CONTROLLING FLUID FLOW,” which is hereby incorporated by reference herein.

### FIELD

The present disclosure generally relates to fluid systems, and more particularly, to controlling the flow of fluids in fluid systems.

### BACKGROUND

Fluid systems, for example gas delivery systems, commonly employ flow control devices to control the flow of fluids in fluid systems. The flow control devices generally include structures sized and dimensioned to impart desired flow characteristics into fluid flowing through the fluid system, such as distribution and mass flow rate. In some fluid systems performance of a flow control device may change over time, for example due to erosion of a structure otherwise sized and dimensioned to control fluid flow within the fluid system and/or due to a force exerted on the flow control structure. In such fluid systems it can be necessary to take the fluid system out of service to restore performance of the flow control device back to a desired condition, such as by reconditioning or replacing the flow control structure. Taking the fluid system out of service may in turn limit availability and/or increase cost of ownership of the fluid system.

Such systems and methods have generally been acceptable for their intended purpose. However, there remains a need for improved injection flange assemblies, semiconductor processing systems and chamber arrangements including injection flange assemblies, and methods of making injection flange assemblies and controlling fluid flows. The present disclosure provides a solution to this need.

### SUMMARY OF THE DISCLOSURE

An injection flange assembly is provided. The injection flange assembly includes a flange body with a first face and a second face separated by a thickness. One or more recess is defined within the first face of the flange body. A flange body lateral slit extends through the thickness of the flange body and couples the first face of the flange body to the second face of the flange body. One or more fluid channel is defined within the thickness of the flange body and fluidly couples the one or more recess defined in the first face of the flange body to an edge of the flange body. One or more first threaded aperture and one or more second threaded aperture are defined within the first face of the flange body, the one or more first threaded aperture separating the edge from the second threaded aperture, the one or more second threaded aperture separating the one or more first threaded aperture from the one or more recess and/or the flange body lateral slit defined within the first face of the flange body.

In addition to one or more of the features described above, or as an alternative, further examples of the injection flange assembly may include one or more conduit and one or more union. The one or more conduit may be coupled to the edge of the flange body. The one or more union may be coupled to the one or more conduit. The one or more union may be in fluid communication with the flange body lateral slit through the one or more recess, the one or more fluid channel, and the one or more fluid channels defined within the flange body.

In addition to one or more of the features described above, or as an alternative, further examples of the injection flange assembly may include one or more first mass flow controller (MFC) device and one or more second MFC device. The one or more first MFC device may be coupled to the one or more union. The one or more second MFC device may also be coupled to the one or more union. The one or more union may be configured to intermix a first fluid (e.g., a first gas) provided by the one or more first MFC device with a second fluid (e.g., a second gas) provided by the one or more second MFC device. The one or more union may intermix the first fluid with the second fluid (at least in part) outside of the flange body prior to communication of the intermixed first fluid and second fluid to the one or more recess defined in the first face of the flange body.

In addition to one or more of the features described above, or as an alternative, further examples of the injection flange assembly may include a first fluid source and a second fluid source. The first fluid source may be coupled to the one or more union, for example through the one or more first MFC device. The first fluid source may be configured to communicate a first fluid to the one or more union and therethrough to the one or more recess defined within the first face of the plate body. The second fluid source may also be coupled to the one or more union, for example through the second MFC device. The second fluid source may be configured to communicate a second fluid to the one or more union. The one or more union may be configured to intermix the second fluid with the first fluid prior communication of the first fluid and the second fluid to the one or more recess defined within the first face of the flange body.

In addition to one or more of the features described above, or as an alternative, further examples of the injection flange assembly may include a plate body and one or more fastener. The plate body may abut the first face of the flange body. The plate body may further extend about the flange body lateral slit coupling the first face to the second face of the flange body. The one or more fastener may extend through the plate body. The one or more fastener may be threadedly seated in the one or more first threaded aperture defined in the first face of the plate body. The one or more fastener may compressively fix the plate body to the first face of the flange body.

In addition to one or more of the features described above, or as an alternative, further examples of the injection flange assembly may include that the one or more first threaded aperture may be one of a plurality of first threaded apertures. The plurality of first threaded apertures may be distributed laterally on the first face of the flange body. The plurality of first threaded apertures may separate the edge of the plate body from the flange lateral slit coupling the first face of the flange body to the second face of the flange body.

In addition to one or more of the features described above, or as an alternative, further examples of the injection flange assembly may include that the second threaded aperture is one of a plurality of second threaded apertures and that the one or more fastener is one of a plurality of fasteners. The plurality of fasteners may be seated in respective ones of the plurality of second threaded apertures to transfer load of a gate valve depending therefrom to the flange body without exerting a bending moment on the plate body abutting the flange body.

In addition to one or more of the features described above, or as an alternative, further examples of the injection flange assembly may include that the one or more recess has a triangular profile. The triangular profile may include a vertex, a base segment, a first leg segment, and a second leg segment. The vertex may be proximate the second face of the flange body. The base segment may be proximate the first face of flange body. The first leg segment and the second segment may couple the base segment of the triangular profile to the vertex of the triangular profile.

In addition to one or more of the features described above, or as an alternative, further examples of the injection flange assembly may include that the fluid channel intersects the recess at a fluid channel outlet. The fluid channel outlet may be offset from the vertex of the triangular profile defined by the recess. The fluid channel outlet may be offset from the base segment of the triangular profile defined by the recess.

In addition to one or more of the features described above, or as an alternative, further examples of the injection flange assembly may include triangular profile further include a vertex arcuate segment coupling the first leg segment to the second leg segment. A first base-to-leg arcuate segment coupling the base segment to the first leg segment of the triangular profile defined by the recess. A second base-to-leg segment may couple the base segment to the second leg segment of the triangular profile defined by the recess.

In addition to one or more of the features described above, or as an alternative, further examples of the injection flange assembly may include that the recess is one of a plurality of recesses defined within the first face of the plate body. The plurality of recesses may be distributed laterally between first and second lateral edges of the flange body, for example such that the plurality of recesses separate the flange body lateral slit from the first threaded aperture.

In addition to one or more of the features described above, or as an alternative, further examples of the injection flange assembly may include that there are no recesses defined in the second face of the flange body between the flange body lateral slit and the edge of the flange body. The second face may have continuous and uninterrupted planar contour between the lateral slot and the edge of the flange body.

In addition to one or more of the features described above, or as an alternative, further examples of the injection flange assembly may include one or more threaded member and a gate valve. The one or more threaded member may be seated in the one or more second threaded aperture. The gate valve may depend from the one or more threaded member and therethrough from the flange body of the injection flange assembly.

A chamber arrangement is provided. The chamber arrangement includes a chamber body, a substrate support, and an injection flange assembly as described above. The chamber body has an injection end and an exhaust end, the exhaust end of the chamber body longitudinally opposite the injection of the chamber body. The substrate support is supported within the chamber body for rotation about a rotation axis between the injection end and the exhaust end of the chamber body. The injection flange assembly abuts the injection end of the chamber body and includes a plate body, a fastener, a threaded member, and a gate valve. The plate body abutting the first face of the flange body and extends about the flange body lateral slit extending through the thickness of the flange body. The fastener extends through the plate body and seated in the first threaded aperture, the fastener compressively fixing the plate body to first face of the plate body. The threaded member extends through the plate body and is seated in the second threaded aperture. The gate valve depends from the threaded member and is carried directly therethrough by the flange body.

A semiconductor processing system is provided. The semiconductor processing system includes an injection flange assembly as described above, a chamber body, a substrate support, a process fluid source, and a controller. The chamber body has an injection end and a longitudinally opposite exhaust end. The substrate support is arranged within an interior of the chamber body. The injection flange assembly abuts the injection end of the chamber body and is separated from the exhaust end of the chamber body by the substrate support. The process fluid source includes a process fluid and is coupled to the injection flange assembly. The controller is operatively connected to the process fluid source and responsive to instructions recorded on a memory to communicate a process fluid to the fluid channel using the process fluid source, flow the process fluid to the recess through the fluid channel, and issue the process fluid into the flange body lateral slit from the recess to deposit a material layer onto a substrate seated on the substrate support.

A method of making an injection flange assembly is provided. The method includes forming the flange body by defining a flange body lateral slit in flange body, the lateral slit extending through a thickness of the flange body, the flange body lateral slit coupling a first face of the flange body to a second face of the flange body, the second face of the flange body separated from the first face of the flange body by the thickness of the flange body; defining a recess in a first face of a flange body; defining a first threaded aperture in the first face of the flange body; defining a second threaded aperture in the first face of the flange body at a location whereat the first threaded aperture separates the edge of the flange body from the second threaded aperture and the second threaded aperture separates the first threaded aperture from the recess; and defining a fluid channel within the thickness of the flange body, the fluid channel coupling an edge of the flange body to the recess defined in the first face of the flange body, the edge coupling the first face of the flange body to the second face of the flange body, the recess thereby fluidly coupling the fluid channel to the flange body lateral slit extending through the thickness of the flange body.

In addition to one or more of the features described above, or as an alternative, further examples of the method may include coupling a first fluid conduit with a union arranged therealong to the edge of the flange body such that the first fluid conduit is fluidly coupled to the fluid channel and coupling a second fluid conduit to the union, the second fluid conduit thereby fluidly coupled to the fluid channel.

In addition to one or more of the features described above, or as an alternative, further examples of the method may include that defining the recess further includes defining the recess with a triangular profile such that the triangular profile has a vertex proximate the second face of the flange body and a base segment proximate the first face of the flange body.

In addition to one or more of the features described above, or as an alternative, further examples of the method may include fixing a plate body to the flange body having a plate body lateral slit extending therethrough, a fastener aperture extending through the plate body, and a through-hole extending through the plate body; registering the plate body lateral slit to the flange body lateral slit, whereby the fastener aperture is registered to the first threaded aperture and the through-hole is registered to the second threaded aperture; and threadedly seating a fastener in the first threaded aperture defined within the first face of the flange body and through the fastener aperture defined in the plate body.

In addition to one or more of the features described above, or as an alternative, further examples of the method may include fixing a gate valve to the flange body, the gate valve including a gate valve body defining a gate valve lateral slit therethrough. Fixing the gate valve to the flange body may further include inserting a threaded member in the through-hole defined in the plate body, threadedly seating the threaded member in the second threaded aperture of the flange body, threadedly seating a clamp member on the threaded member, registering the gate valve lateral slit to the flange body lateral slit, and advancing the threaded member into the second threaded aperture such that the clamp member compressively fixes the gate valve against the plate body and load of the gate valve is carried directly by the flange body.

A flow control method is provided. The method includes, at an injection flange assembly as described above, communicating a process fluid to the fluid channel, flowing the process fluid to the recess through the fluid channel, and issuing the process fluid into the flange body lateral slit from the recess.

In addition to one or more of the features described above, or as an alternative, further examples of the flow control method may include that the process fluid comprises a silicon-containing material layer precursor and a dopant-containing material layer precursor. The method may further include intermixing the dopant-containing material layer precursor with the silicon-containing material layer precursor prior to communicating the process fluid to the fluid channel.

In addition to one or more of the features described above, or as an alternative, further examples of the flow control method may include depositing a material layer onto a substrate using the process fluid. Either (or both) cross-substrate film thickness variation and/or cross-substrate dopant concentration variation may be limited by controlling fluid velocity variation using shape of the recess defined within the first face of the flange body.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

The following descriptions should not be considered limiting in any way. With reference to accompanying drawings, like elements are numbered alike:

FIG. 1 is a schematic view of a semiconductor processing system including a chamber arrangement with an injection flange assembly in accordance with the present disclosure, schematically showing the chamber arrangement coupling a fluid source to an exhaust source.

FIG. 2 is a schematic view of the chamber arrangement and a controller included in the semiconductor processing system of FIG. 1 according to an example the disclosure, schematically showing elements of both the chamber arrangement and elements of the controller.

FIG. 3 is a schematic view of the fluid source and injection flange assembly of FIG. 1 according to an example of the disclosure, schematically showing mass flow controller (MFC) devices coupling a plurality of fluid sources to the injection flange assembly.

FIG. 4 is an exploded view of the injection flange assembly of FIG. 1 according to an example of the disclosure, schematically showing a plate body, a gate valve, a plurality of fasteners, and a plurality of threaded members exploded away from a plate body according to an example of the disclosure.

FIG. 5 is an end view of the flange body included in the injection flange assembly of FIG. 1 according to an example of the disclosure, schematically showing recesses and threaded apertures laterally distributed between an edge and a flange body of the flange body from the perspective of an interior of a chamber body included in the chamber arrangement.

FIG. 6 is an end view of the plate body included in the injection flange assembly of FIG. 1 according to an example of the disclosure, schematically showing fastener apertures and threaded member passthroughs defined between an edge and a plate body lateral slit of the plate body.

FIG. 7 is an end view of the gate valve included in the injection flange assembly according to an example of the disclosure, schematically showing a mounting flange spanning a gate valve lateral slit of the gate valve for fixation of the gate valve to the flange body.

FIG. 8 is longitudinal cross-sectional view of the injection flange assembly of FIG. 1 according to an example of the disclosure, schematically showing a threaded member cooperating with a flange body to directly carry load of a gate valve.

FIG. 9 is a lateral cross-sectional view of the injection flange assembly of FIG. 1 according to an example of the disclosure, schematically showing a recess within a face of the flange body bounded by the plate body of the injection flange assembly.

FIG. 10 is a partial lateral cross-sectional view of the injection flange assembly of FIG. 1 according to an example of the disclosure, schematically showing fluid introduced into the recess from a fluid channel outlet issuing from a port defined between the plate body and the flange body according shape of the recess and contour of the plate body.

FIG. 11 is chart of velocity of a fluid issued from a port of the injection flange assembly of FIG. 1 and that of another injection flange assembly, comparatively showing velocity variation of fluids issued from ports of injection flange assembly.

FIGS. 12-15 are block diagrams of methods of making injection flange assemblies and controlling fluid flows in accordance with an example of disclosure, showing operations of the methods according to non-limiting examples of the methods.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

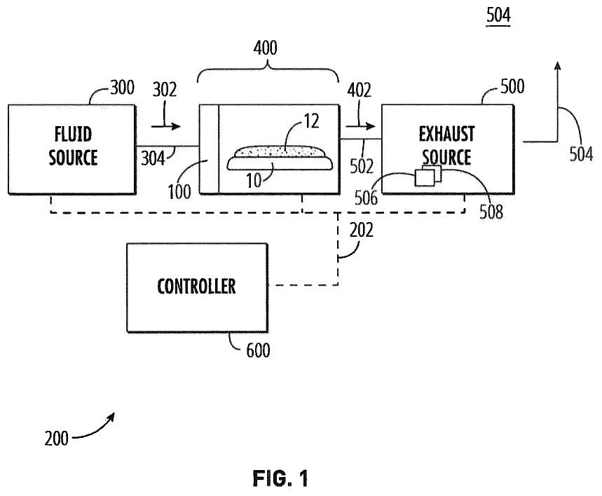

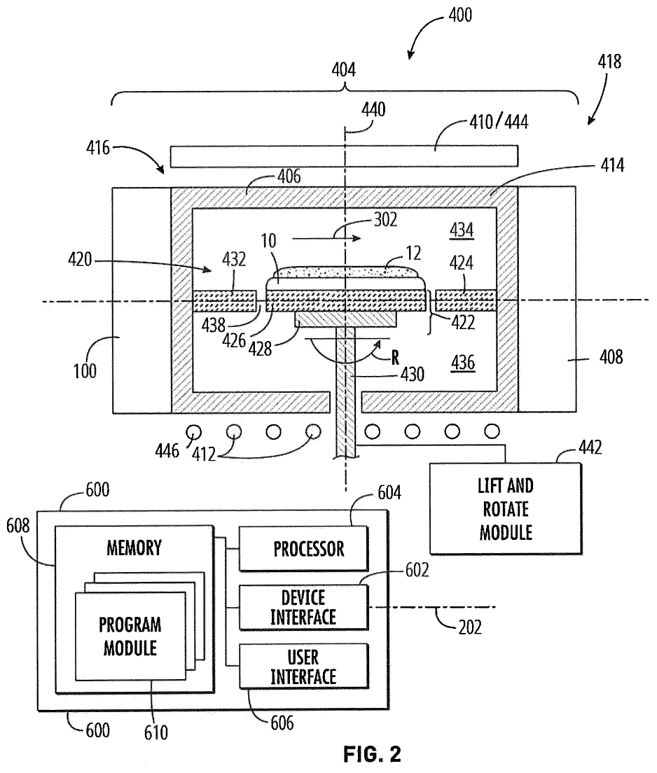

Reference will now be made to the drawings wherein, like reference numerals identify similar structural features or aspects of the subject disclosure. For purposes of explanation and illustration, and not limitation, a partial view of an injection flange assembly in accordance with the present disclosure is shown in FIG. 1 and is designated generally by reference character 100. Other examples of injection flange assemblies, chamber arrangements and semiconductor processing systems including injection flange assemblies, and related methods of making injection flange assemblies and controlling fluid flows in accordance with the present disclosure, or aspects thereof, are provided in FIG. 2 through FIG. 15, as will be described. The systems and methods of the present disclosure may be used to control a process fluid introduced into chamber arrangements for semiconductor processing systems, such as in semiconductor processing systems employed to deposit silicon-containing material layers onto substrates using epitaxial deposition techniques, though the present disclosure is not limited to any particular type of material layer or to semiconductor processing systems in general.

Referring to FIG. 1, a semiconductor processing system 200 including the injection flange assembly 100 is shown according to an example of the present disclosure. In the illustrated example the semiconductor processing system 200 includes a fluid source 300, a chamber arrangement 400, an exhaust source 500, and a controller 600. The fluid source 300 includes a process fluid 302, is coupled to the chamber arrangement 400 by a process fluid supply conduit 304, and is configured to communicate the process fluid 302 to the chamber arrangement 400 through the process fluid supply conduit 304. The chamber arrangement 400 includes the injection flange assembly 100 and is configured to contact a substrate 10 supported within an interior of the chamber arrangement 400 under conditions selected to cause deposition of a material layer 12 onto the substrate 10, for example temperature and/or pressure as well as mass flow rate of the process fluid 302 introduced into the interior of the chamber arrangement 400.

The exhaust source 500 is coupled to the chamber arrangement 400 by an exhaust conduit 502 and is configured to communicate an exhaust fluid 402 issued by the chamber arrangement 400 to an external environment 504 outside of the semiconductor processing system 200. In this respect it is contemplated that the exhaust source 500 include one or more of a vacuum pump 506 and an abatement apparatus 508, the vacuum pump 506 configured to maintain a predetermined deposition pressure within the interior of the chamber arrangement 400, the abatement apparatus 508 in turn configured to remove residual process fluid and/or reaction products from the exhaust fluid 402 prior to communication of the exhaust fluid 402 to the external environment 504. In certain examples the predetermined deposition pressure may be a predetermined atmospheric deposition pressure. The predetermined atmospheric deposition pressure may be, for example, between about 760 Torr and about 700 Torr. In accordance with certain examples, the predetermined deposition pressure may be a predetermined reduced pressure deposition pressure. The predetermined reduced pressure deposition pressure may be, for example, between about 700 Torr and about 0.1 Torr.

It is contemplated that the controller 600 be operatively connected to one or more of the fluid source 300, the chamber arrangement 400, and the exhaust source 500 to control deposition of the material layer 12 onto the substrate 10. In this respect the semiconductor processing system 200 may include a wired or wireless link 202. The wired or wireless link 202 may in turn couple the controller 600 to one or more of the fluid source 300, the chamber arrangement 400, and/or the exhaust source 500. Although shown and described herein in the context as being configured for material layer deposition, it is to be understood and appreciated that the semiconductor processing system 200 may alternatively (or additionally) be configured for material removal and remain within the scope of the present disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN), and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the chamber arrangement 400 and the controller 600 are shown according to examples of the disclosure. In the illustrated example the chamber arrangement 400 has single-substrate crossflow architecture 404 and includes the injection flange assembly 100, a chamber body 406, an exhaust flange 408, an upper heater element array 410, and a lower heater element array 412. It is contemplated that the chamber body 406 be formed from a transparent material 414 (e.g., a ceramic material transparent to electromagnetic radiation within an infrared waveband) and has injection end 416 and an exhaust end 418 longitudinally opposite the injection end 416. The injection flange assembly 100 abuts the injection end 416 of the chamber body 406 and couples the supply conduit to an interior 420 of the chamber body 406. The exhaust flange 408 abuts the exhaust end 418 of the chamber body 406 and couples the chamber body 406 to the exhaust conduit 502. Non-limiting examples of suitable transparent materials 414 include quartz, fused silica, and sapphire. Although shown and described herein as having a generally planar shape, it is to understood and appreciated that the chamber body 406 may defined an arcuate or dome-like profile and/or define a plurality of external ribs extending laterally about an exterior surface of the chamber body 406 and longitudinally spaced apart from one another between the injection end 416 and the exhaust end 418 of the chamber body 406.

It is contemplated that chamber arrangement 400 includes a process kit 422. In the illustrated example the process kit 422 includes a divider 424, a substrate support 426 (e.g., a susceptor), a support member 428, and a shaft member 430. The divider 424 is fixed within the interior 420 of the chamber body 406, is formed from an opaque material 432 (e.g., a material opaque to electromagnetic radiation within an infrared waveband), and divides the interior 420 of the chamber body 406 into an upper chamber 434 and a lower chamber 436. The divider 424 further defines a divider aperture 438 therethrough, the divider aperture 438 in turn coupling the upper chamber 434 of the chamber body 406 to the lower chamber 436 of the chamber body 406. In certain examples of the opaque material 432 may include a bulk carbonaceous material, which may or may not have a ceramic coating. Non-limiting examples of suitable carbonaceous materials include graphite and pyrolytic carbon. A non-limiting example of a suitable ceramic material includes silicon carbide. It is also contemplated that the divider 424 may be formed from a bulk ceramic material, such as silicon carbide by way of illustration and not for limitation.

The substrate support 426 may be formed from an opaque material (e.g., the opaque material 432), arranged at least in part within the divider aperture 438, and configured to support the substrate 10 during deposition of the material layer 12 onto the substrate 10. The substrate support 426 may further be supported for rotation R about a rotation axis 440 and configured to rotate the substrate 10 about the rotation axis 440 during deposition of the material layer 12 onto the substrate 10. The support member 428 is formed from a transparent material (e.g., the transparent material 414), is arranged along the rotation axis 440 and within the lower chamber 436 of the chamber body 406, and is fixed and fixed in rotation R relative to the substrate support 426 about the rotation axis 440. The shaft member 430 may also be formed from a transparent material (e.g., the transparent material 414), is arranged along the rotation axis 440 and fixed in rotation R about the rotation axis 440 relative to the support member 428, and extends within the lower chamber 436 and through a lower wall of the chamber body 406. It is contemplated that the shaft member 430 operably couple the substrate support 426 to a lift and rotate module 442 through the support member 428. It is also contemplated that the lift and rotate module 442 further be configured to rotate the substrate support 426 about the rotation axis 440 and seat/unseat the substrate 10 from the substrate support 426, for example using a lift pin actuator and lift pin arrangement. Examples of suitable lift pin actuator and lift pin arrangements include those shown and described in U.S. Patent Application Publication No. 2024/0112946A1 , filed on Sep. 27, 2023, the contents of which are incorporated herein by reference in its entirety.

The upper heater element array 410 is supported above the chamber body 406 and is configured to heat the substrate 10 using electromagnetic radiation within an infrared waveband. In this respect it is contemplated that the upper heater element array 410 be configured to heat the substrate 10 to a predetermined material layer deposition temperature, for example to a predetermined material layer deposition temperature that is between about 200 degrees Celsius and about 1300 degrees Celsius. In the illustrated example the upper heater element array 410 includes a plurality of filament-type linear lamps 444. The plurality of filament-type linear lamps 444 extend longitudinally above the chamber body 406 between the injection end 416 and the exhaust end 418 of the chamber body 406. Individual ones of the plurality of filament-type linear lamps 444 may in turn be laterally spaced apart from one another between laterally opposite sidewalls of the chamber body 406, and may be substantially parallel to one another.

The lower heater element array 412 is similar to the upper heater element array 410, is additionally supported below the chamber body 406, and may further include a plurality of lower filament-type linear lamps 446. Individual ones of the plurality of lower filament-type linear lamps 446 may be longitudinally spaced apart from one another between the injection end 416 and the exhaust end 418 of the chamber body 406, substantially orthogonal to the plurality of upper filament-type linear lamps 444, and be substantially parallel to one another. Although shown and described herein as both including filament-type linear lamps, it is to be understood and appreciated that either (or both) the upper heater element array 410 and the lower heater element array 412 may include bulk-type lamps and/or other types of heater elements and remain within the scope of the present disclosure.

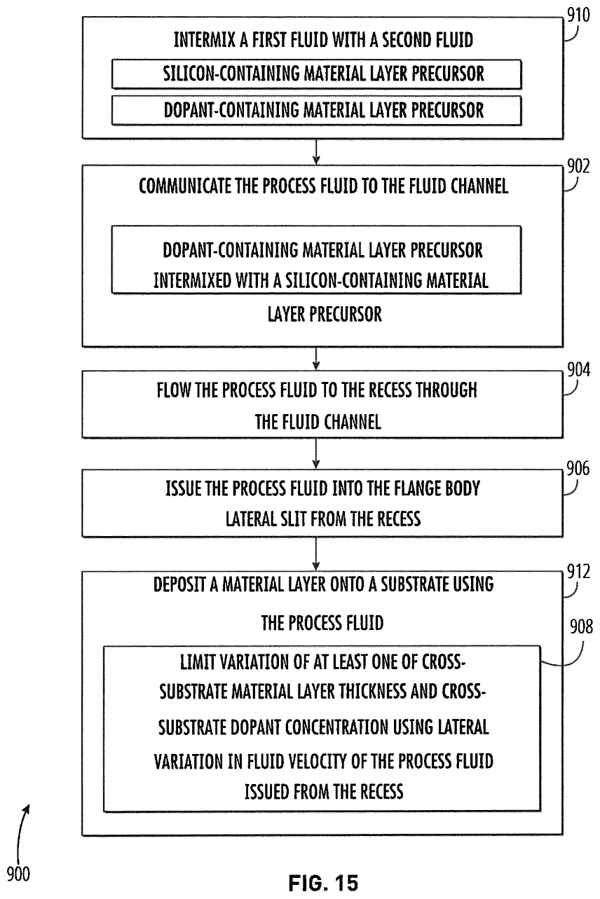

As also shown in FIG. 2 the controller 600 may include a device interface 602, a processor 604, a user interface 606, and a memory 608. The device interface 602 couples the processor 604 to the wired or wireless link 202 and therethrough to one or more of the fluid source 300 (shown in FIG. 1), the chamber arrangement 400, and the exhaust source 500 (shown in FIG. 1). The processor 604 is operatively coupled to the user interface 606, for example to provide a user output and/or receive a user input therethrough, and is disposed in communication with the memory 608. It is contemplated that the memory 608 in turn includes a non-transitory machine-readable medium having a plurality of program modules 610 recorded thereon that, when read by the processor 604, cause the processor 604 to execute certain operations. Among the operations are operations of a material layer deposition method 800 (shown in FIG. 15), as will be described. Although shown and described herein as having a specific architecture it is to be understood and appreciated that the controller 600 may have other architectures in other examples of the disclosure, such as a distributed computing architecture, and remain within the scope of the present disclosure.

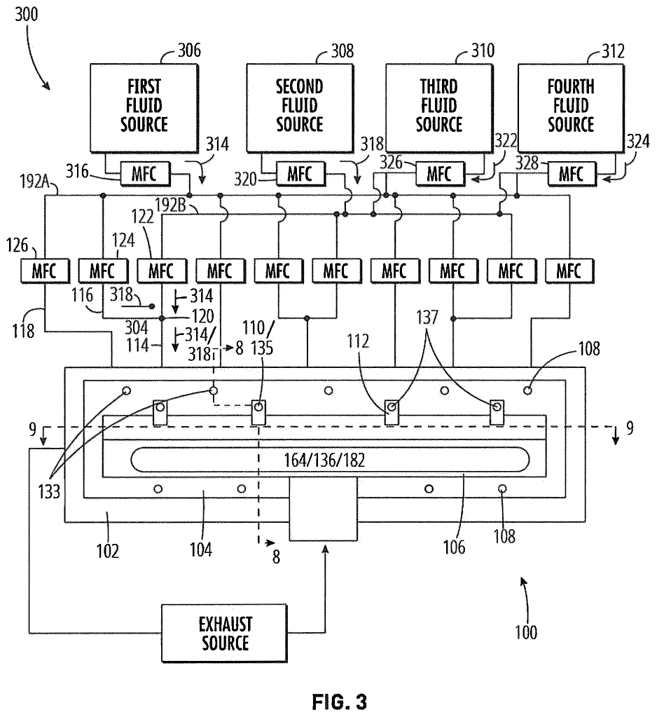

With reference to FIG. 3, the fluid source 300 and the injection flange assembly 100 are shown according to an example of the disclosure. In the illustrated example the fluid source 300 includes a first fluid source 306, a second fluid source 308, a third fluid source 310, and a fourth fluid source 312. The first fluid source 306 may include one or more silicon-containing material layer precursor 314. The first fluid source 306 may also be coupled to the chamber arrangement 400 (shown in FIG. 1) by a first fluid source mass flow controller (MFC) device 316 and the process fluid supply conduit 304, the first fluid source MFC device 316 in turn operably associated with the controller 600 (shown in FIG. 1). It is contemplated that the first fluid source 306 further be configured to communicate a flow of the silicon-containing material layer precursor 314 to the interior 420 (shown in FIG. 2) of the chamber body 406 (shown in FIG. 2) through the injection flange assembly 100. In this respect the first fluid source 306 may be configured to communicate the silicon-containing material layer precursor 314 to the chamber arrangement 400 as a gas, for example as a flow consisting of (or consisting essentially of) as a gas. Examples of suitable first fluid source MFC devices include 5850 EM Series MFC devices, available from Brooks Instrument, LLC of Hatfield, Pennsylvania.

In certain examples the one or more silicon-containing material layer precursor 314 may include a chlorinated silicon-containing material layer precursor. Non-limiting examples of suitable chlorinated silicon-containing material layer precursors include dichlorosilane (SiH₂Cl₂), trichlorosilane (SiHCl₃), and silicon tetrachloride (SiCl₄). In accordance with certain examples the one or more silicon-containing material layer precursor 314 may include a non-chlorinated silicon-containing material layer precursor. Non-limiting examples of suitable non-chlorinated silicon-containing material layer precursor include silane (SiH₄), disilane (Si₂H₆), and trisilane (Si₃H₈). As will appreciated by those of skill in the art in view of the present disclosure, higher order chlorinated silicon-containing material layer precursors and/or non-chlorinated silicon-containing material layer precursors may be employed in the semiconductor processing system 200 and remain within the scope of the present disclosure.

The second fluid source 308 may be similar to the first fluid source 306 and additionally include a dopant-containing material layer precursor 318. The second fluid source 308 is further coupled to the chamber arrangement 400 (shown in FIG. 1) by a second fluid source MFC device 320 and the process fluid supply conduit 304 to the injection flange assembly 100, the second fluid source MFC device 320 in turn be operatively associated with the controller 600 (shown in FIG. 1). It is contemplated that the second fluid source 308 by configured to communicate the dopant-containing material layer precursor 318 and be configured to communicate a flow of the dopant-containing material layer precursor 318 to the chamber arrangement 400.

In certain examples the dopant-containing material layer precursor 318 may include an n-type dopant like phosphorous (P) and/or arsenic (As), which may be communicated using flow(s) of arsine (AsH₃) and/or phosphine (PH₃) by way of non-limiting example. In accordance with certain examples, the dopant-containing material layer precursor 318 may include a p-type dopant, such as boron (B), which may include a dopant-containing material layer precursor like diborane (B₂H₆) by way of non-limiting example. It is also contemplated that the dopant-containing material layer precursor 318 may include carbon (C) and/or tin (Sn), which may be communicated using methylsilane (H₃SiCH₃) and/or tin tetrachloride (SnCl₄) by way of non-limiting example. It is further contemplated that the second fluid source 308 may include an alloying constituent, such as germanium (Ge) as communicated using germane (GeH₄) and/or germanium tetrachloride (GeCl₄) by way of illustration and not for limitation, and remain within the scope of the present disclosure.

The third fluid source 310 and the fourth fluid source 312 may also be similar to the first fluid source 306 and additionally include an etchant-containing fluid 322 (e.g., an etchant intermixed with a carrier fluid) and a carrier/purge fluid 324, respectively. In this respect the third fluid source 310 may be coupled to the chamber arrangement 400 (shown in FIG. 1) by one or more third fluid source MFC device 326 and the one or more process fluid supply conduit 304 through the injection flange assembly 100. The one or more third fluid source MFC device 326 may be operably associated with the controller 600 (shown in FIG. 1), and the third fluid source 310 configured to communicate a flow of the etchant-containing fluid 322 to the chamber arrangement 400 through the injection flange assembly 100. The fourth fluid source 312 may be coupled to the chamber arrangement 400 (shown in FIG. 1) by one or more fourth fluid source MFC device 328 and the one or more process fluid supply conduit 304 through the injection flange assembly 100. The one or more fourth fluid source MFC device 328 may further be operably associated with the controller 600 (shown in FIG. 1) and configured to communicate the carrier/purge fluid 324 to the chamber arrangement 400 through the injection flange assembly 100, for example independently and/or intermixed with one or more of the silicon-containing material layer precursor 314, the dopant-containing material layer precursor 318, and the etchant-containing fluid 322. In certain examples the etchant-containing fluid 322 may include a halide-containing material. Non-limiting examples of suitable halides include fluorine (F) and chlorine (Cl) containing materials such as chlorine trifluoride (ClF₃), hydrochloric (HCl) acid, and chlorine (Cl₂) gas. In accordance with certain examples, the carrier/purge fluid 324 may include hydrogen (H₂) gas or an inert gas. Non-limiting examples of suitable inert gases include nitrogen (N2) gases as well as noble gases like argon (Ar) gas, krypton (Kr) gas, and helium (He) gas.

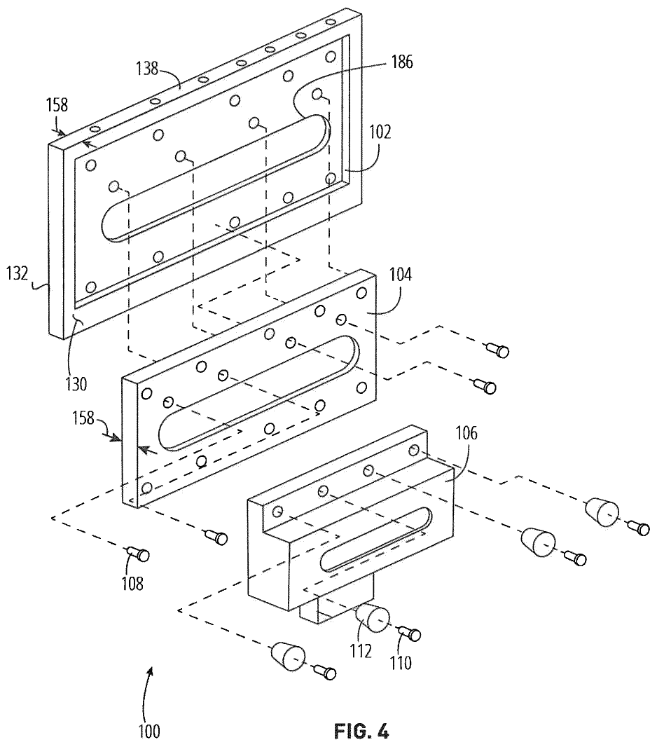

With reference to FIG. 4 and continuing reference to FIG. 3 the injection flange assembly 100 includes a flange body 102, a plate body 104, a gate valve 106, a fastener 108, a threaded member 110, and a clamp member 112. As shown and described herein the injection flange assembly 100 also includes a first fluid conduit 114, a second fluid conduit 116, a third fluid conduit 118, a union 120, a first MFC device 122, a second MFC device 124, and a third MFC device 126. The plate body 104 abuts the flange body 102 and is fixed thereto by the fastener 108. The gate valve 106 abuts the plate body 104, is separated from the flange body 102 by the plate body 104, and depends from the threaded member 110, which in turn extends through the plate body 104 and the threadedly seated in the flange body 102. The clamp member 112 is seated on the threaded member 110 opposite the flange body 102 and compressively urges the gate valve 106 against the plate body 104. In the illustrated example the fastener 108 is one of a plurality of fasteners 108 coupling the plate body 104 to the flange body 102, the threaded member 110 is one of a plurality of threaded members 110 from which the gate valve 106 depends, and the clamp member 112 in one of a plurality of clamp members 112 compressively urging the gate valve 106 against the plate body 104. Although a certain number of fasteners 108, threaded members 110, and clamp members 112 are shown, it is to be understood and appreciated that fewer or additional fasteners 108, threaded members 110, and/or clamp members 112 may be included in the injection flange assembly 100 in other examples and remain within the scope of the present disclosure.

The first fluid conduit 114 couples the first MFC device 122 to the flange body 102, the first MFC device 122 in turn coupling the second fluid source 308 to the first fluid conduit 114 and therethrough the flange body 102. It is contemplated that the union 120 be arranged along the first fluid conduit 114 to intermix a first fluid (e.g., the silicon-containing material layer precursor 314 received from the first MFC device 122) with a second fluid (e.g., the dopant-containing material layer precursor 318 received from the second MFC device 124) prior to communication to a recess 186 (shown in FIG. 4) defined in the first face 130 of the flange body 102, that the second fluid conduit 116 couple the second MFC device 124 to the flange body 102 through the union 120, and that the second MFC device 124 in turn couple the first fluid source 306 to the flange body 102. The third fluid conduit 118 couples the third MFC device 126 to the flange body 102, the third MFC device 126 in turn further coupling the first fluid source 306 to the flange body 102. In the illustrated example the first fluid conduit 114 is one or a plurality of first fluid conduits 114, the second fluid conduit 116 is one or a plurality of second fluid conduits 116, the third fluid conduit 118 is one of a plurality of third fluid conduits 118; the first MFC device 122 is one of a plurality of first MFC devices 122, the second MFC device 124 is one of a plurality of second MFC devices 124, and the third MFC device 126 is one of a plurality of third MFC device 126; and the union 120 is one of a plurality of union 120. Although a certain number of each element is shown in the illustrated example, it is to be understood and appreciated that other numbers of the elements may be employed in other examples of the injection flange assembly 100 and remain within the scope of the present disclosure.

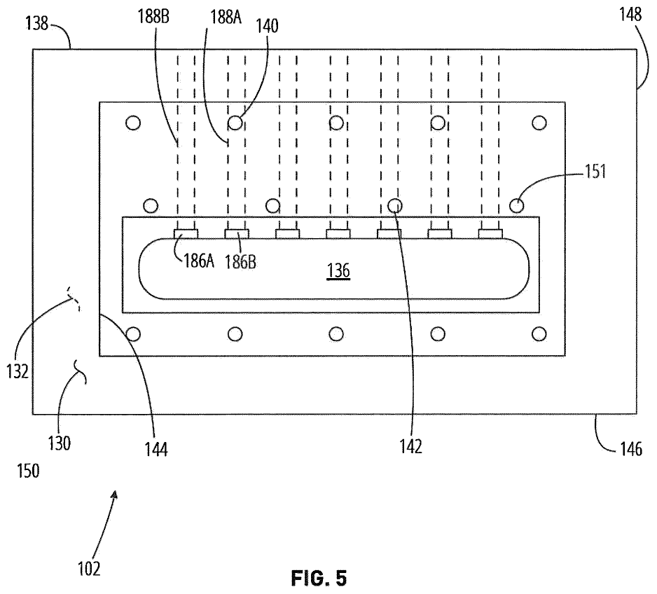

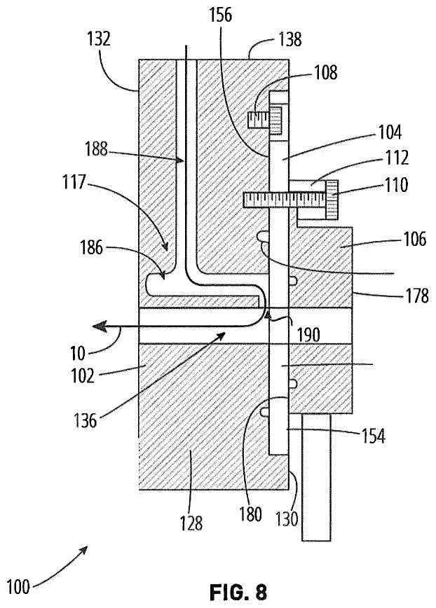

With reference to FIG. 5 and continuing reference to FIG. 4, the flange body 102 is shown according to an example of the disclosure. The flange body 102 is formed from a flange body material 128 (shown in FIG. 8) and has a first face 130 separated from a second face 132 by a thickness 158 (shown in FIG. 4) of the flange body 102. It is contemplated that the second face 132 be configured to bound the interior 420 (shown in FIG. 2) of the chamber body 406 (shown in FIG. 2), that the first face 130 be configured to seat thereon the plate body 104 (shown in FIG. 3), and that the first face 130 and the second face 132 define therethrough a flange body lateral slit 136 coupling the first face 130 of the flange body 102 to the second face 132 of the flange body 102. In this respect the second face 132 may be generally planar, and extend continuously and without interruption between the flange body lateral slit 136 and an edge 138 of the flange body 102, that the first face 130 define therein a first threaded aperture 140 and a second threaded aperture 142 therein within a plate body seat 144, and that the flange body lateral slit 136 be sized and dimensioned to permit transfer of the substrate 10 (shown in FIG. 1) therethrough. In certain examples the flange body material 128 may include (or consist of or consist essentially of) a stainless steel material. In accordance with certain examples, the flange body material 128 may be a low copper content stainless steel material, which limits likelihood of incorporating copper (Cu) into the substrate 10 and/or the material layer 12 (shown in FIG. 1).

In certain examples the flange body 102 may be generally rectangular in shape. In this respect the edge 138 may be a first longitudinal edge 138 and the flange body 102 may have a second longitudinal edge 146, a first lateral edge 148, and a second lateral edge 150. The first longitudinal edge 138 may be separated from the second longitudinal edge 146 by the flange body lateral slit 136 and coupled thereto by the first lateral edge 148 and the second lateral edge 150. The second longitudinal edge 146 may be substantially parallel to the first longitudinal edge 138. The second longitudinal edge 146 may further be substantially orthogonal to either (or both) the first lateral edge 148 and the second lateral edge 150 of the flange body 102. It is contemplated that the second lateral edge 150 of the flange body 102 may be substantially parallel to the first lateral edge 148 of the flange body 102. Although shown and described herein as being substantially rectangular in shape, it is to be understood and appreciated that the flange body 102 may have different shapes in other examples, for example polygonal and/or arcuate, and remain within the scope of the present disclosure.

In certain examples the second face 132 of the flange body 102 may be substantially planar in contour. In this respect it is contemplated that the second face 132 may be substantially planar (e.g., continuous, and uninterrupted) between the flange body lateral slit 136 and the first longitudinal edge 138. In further respect, it is also contemplated that the second face 132 of the flange body 102 may be substantially planar (e.g., continuous, and uninterrupted) between the flange body lateral slit 136 and the second longitudinal edge 146. In accordance with certain examples, the first face 130 of the flange body 102 may define therein a plate body seal member seat 151. The plate body seal member seat 151 may extend about the flange body lateral slit 136 and seat a flange body-to-plate body seal member 153 therein (shown in FIG. 8). As will be appreciated by those of skill in the art in view of the present disclosure, employment of the flange-body-to-plate body seal member 153 may enable the flange body 102 to be formed with a relatively loose flatness tolerance, simplifying fabrication and/or limiting cost of the injection flange assembly 100 (shown in FIG. 1).

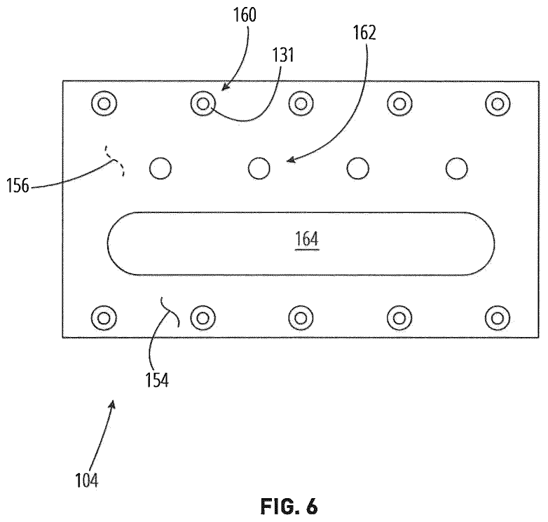

With reference to FIG. 6 and continuing reference to FIG. 4, the plate body 104 is shown according to an example of the disclosure. It is contemplated that the plate body 104 be formed from a plate body material 152 (shown in FIG. 8) and has a first face 154 separated from a second face 156 by a thickness 158 (shown in FIG. 4) of the plate body 104. It is also contemplated that the plate body 104 defines a plate body fastener aperture 160, a through-hole 162, and a plate body lateral slit 164 extending through the thickness 158 of the plate body 104, and coupling the first face 154 of the plate body 104 to the second face 156 of the plate body 104. The plate body fastener aperture 160 is configured to receive therethrough the fastener 108 for fixation of the plate body 104 to the flange body 102 when the plate body 104 is registered to the flange body 102 (shown in FIG. 3). In this respect it is contemplated that the plate body fastener aperture 160 defines therein a head portion seat 131 therein, the head portion seat 131 defined within the thickness 158 of the plate body 104 and at a depth selected such a head of the fastener 108 (shown in FIG. 3) is recessed below the first face 154 of the plate body 104. As will be appreciated by those of skill in the art in view of the present disclosure, recessing the head of the fastener 108 enables flush mounting of the gate valve 106 (shown in FIG. 3) to the plate body 104, simplifying sealing of the plate body lateral slit 164 from the external environment 504 (shown in FIG. 1) outside of the injection flange assembly 100. It is further contemplated that the plate body fastener aperture 160 may be unthreaded, simplifying fabrication of the plate body 104. In certain examples the fastener 108 may be captive within the plate body fastener aperture 160, simplifying assembly and/or maintenance of the injection flange assembly 100, and remain within the scope of the present disclosure.

The through-hole 162 is configured to receive therethrough the threaded member 110 when the plate body 104 is registered to the flange body 102. In this respect it is contemplated that the flange body 102 correspond in size and dimensions to the plate body seat 144 (shown in FIG. 5) such that, when the plate body 104 is received in the plate body seat 144, the plate body fastener aperture 160 is registered to a first threaded aperture 140 defined in the first face 130 of the flange body 102 to fix the plate body 104 to the flange body 102, and the through-hole 162 is registered to a second threaded aperture 142 defined in the first face 130 of the flange body 102 to support the gate valve 106 directly with the flange body 102 while limiting (or eliminating) a bending moment M (shown in FIG. 8) exerted on the plate body 104, and the plate body lateral slit 164 (shown in FIG. 3) is aligned to the flange body lateral slit 136 for transfer of the substrate 10 (shown in FIG. 1) through the plate body 104 and the flange body 102. In certain examples the through-hole 162 may be unthreaded, simplifying fabrication of the plate body 104. In accordance with certain examples, the threaded member 110 (shown in FIG. 3) may be captive within the through-hole 162, which may also simplify assembly and/or maintenance of the injection flange assembly 100 (shown in FIG. 1).

In certain examples plate body material 152 may include (or consist of or consist essentially of) a stainless steel material. Non-limiting examples of suitable stainless steel materials include 308 stainless, 310 stainless, and 318 stainless. In accordance with certain examples, the plate body material 152 may differ in composition from that of the flange body material 128. In this respect it is contemplated that the plate body material 152 may have a heat transfer coefficient that differs from that of the flange body material 128. For example, the flange body material 128 may include stainless, and the plate body material 152 may include (or consist of or consist essentially of a nickel-base material, such as Hastelloy® by way of non-limiting example. As will be appreciated by those of skill in the art in view of the present disclosure, this can limit heat transfer between the flange body 102 and the gate valve 106, simplifying the injection flange assembly 100 by limiting (or eliminating) need to otherwise cool either (or both) the flange body 102 and the gate valve 106.

In certain examples the plate body fastener aperture 160 may be one of a plurality of plate body fastener apertures 160 defined in the plate body 104, the plurality of plate body fastener apertures 160 in turn corresponding in number and spacing to that of the plurality of first threaded apertures 166 defined in the first face 130 of the flange body 102. It is contemplated that the through-hole 162 may one of a plurality of through-holes 162 defined in the plate body 104, the plurality of through-holes 162 corresponding in number and spacing to that of the plurality of second threaded apertures 168 defined in the first face 130 of the flange body 102. Although shown and described herein as having a specific number of plate body fastener apertures 160 and through-holes 162, it is to be understood and appreciated that the plate body 104 may have a different number of plate body fastener apertures 160 and through-holes 162 in other examples and remain within the scope of the present disclosure.

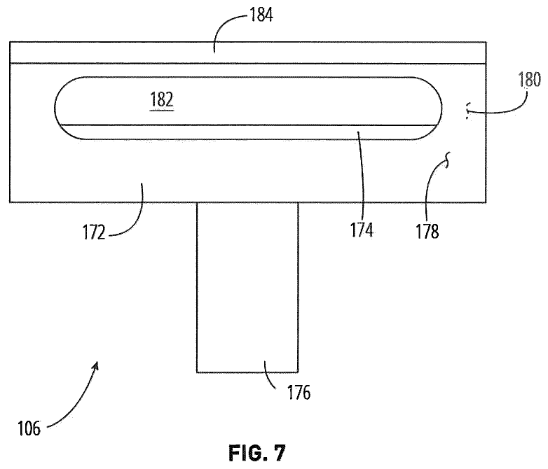

With reference to FIG. 7 and continuing reference to FIG. 4, the gate valve 106 is shown according to an example of the disclosure. In the illustrated example the gate valve 106 includes a gate valve body 172, a gate 174, and a gate actuator 176. The gate valve body 172 has a first face 178 and a second face 180, defines a gate valve lateral slit 182 therethrough coupling the first face 178 of the gate valve body 172 to the second face 180 of the gate valve body 172, and has a flange portion 184 protruding therefrom laterally spanning the gate valve body 172 and configured to receive thereon the clamp member 112 for fixation of the gate valve 106 to the flange body 102 with the plate body 104 compressively fixed therebetween.

The gate 174 is received within the gate valve body 172 and has a first position, whereat the gate valve lateral slit 182 is open such that the substrate 10 (shown in FIG. 1) may be transferred through the gate valve 106 (shown in FIG. 1), and a second position, whereat the gate 174 seals the gate valve lateral slit 182 such that an atmosphere within the interior 420 (shown in FIG. 2) is separated from the external environment 504 (shown in FIG. 1) outside of the chamber body 406 (shown in FIG. 2) by the gate 174. The gate actuator 176 is operably coupled to the gate 174 and is configured to move the gate 174 between the first position and the second position, as required during operation of the semiconductor processing system. In certain examples the gate valve body 172 may be formed from (e.g., consist of or consist essentially of) a stainless steel material. Non-limiting examples of suitable stainless steel materials include low-copper content stainless steel materials such as 308 stainless, 310 stainless, and 316 stainless. Examples of suitable gate valves include V74 series rectangular gate valves, available from the Kurt J. Lesker Company of Jefferson Hills, Pennsylvania.

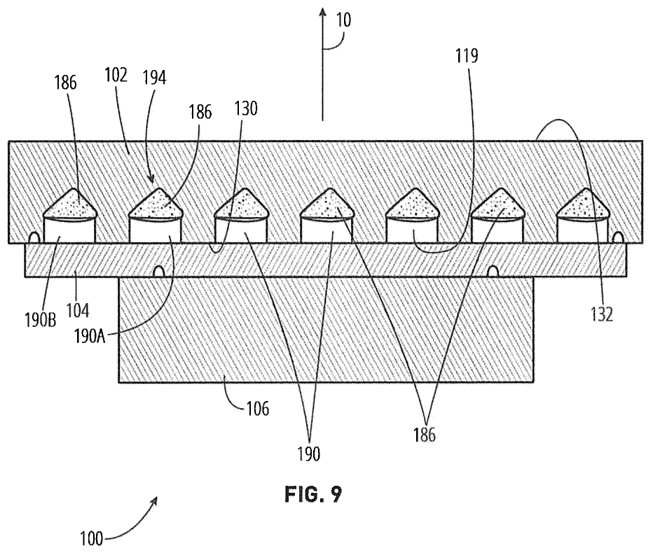

With reference to FIG. 8 to FIG. 11 and continuing reference to FIG. 3, the injection flange assembly 100 is shown according to an example of the disclosure. As shown in FIG. 8, the flange body 102 defines therein the recess 186, a fluid channel 188, and an injection port 190. It is contemplated that the recess 186 may be one of a plurality of recesses 186 defined within the first face 130 of the flange body 102, for example a first recess 186A (shown in FIG. 5) and a second recess 186B (shown in FIG. 5). It is also contemplated that the fluid channel 188 may be one of a plurality fluid channels 188 defined within the thickness 158 (shown in FIG. 4), for example a first fluid channel 188A (shown in FIG. 5) and a second fluid channel 188B (shown in FIG. 5). It is further contemplated that the injection port 190 may be one of a plurality of injection ports 190, for example a first injection port 190A and a second injection port 190B (FIG. 9), each of the injection ports fluidly coupling an individual one of the plurality of fluid channels 188 to the flange body lateral slit 136 through an individual one of the plurality of recesses 186 defined in the first face 130 of the flange body 102.

It is contemplated that the first recess 186A be defined within the first face 130 of the flange body 102 and bounded by the second face 156 of the plate body 104. The first recess 186A is fluidly coupled to the edge 138 of the flange body 102 by the first fluid channel 188A, is bounded by the second face 156 of the plate body 104 and is fluidly coupled to the flange body lateral slit 136 by the first injection port 190A. The first fluid channel 188A is defined within the thickness 158 of the flange body 102, extends between the first recess 186A and the edge 138, and may be substantially orthogonal relative to either (or both) the flange body lateral slit 136 and the edge 138 of the flange body 102. It is also contemplated that the second recess 186B and the second fluid channel 188B be similar to the first recess 186A and the first fluid channel 188A, respectively, additionally be laterally offset from the first recess 186A and the first fluid channel 188A, and further be coupled to the flange body lateral slit 136 by the second injection port 190B. In this respect the second recess 186B is defined within the first face 130 of the flange body 102, is fluidly coupled to the edge 138 of the flange body 102 by the second fluid channel 188B, and is further fluidly coupled to the flange body lateral slit 136 by the second injection port 190B when the plate body 104 is fixed to the flange body 102. In the illustrated example the first recess 186A is one of four (4) first recesses 186A defined in the first face 130 of the flange body 102, the second recess 186B is one of three (3) second recesses 186B defined in the first face 130 of the flange body 102, and the first fluid channel 188A and the second fluid channel 188B are two of seven (7) fluid channels 188 defined within the thickness 158 of the flange body 102. As will be appreciated by those of skill in the art in view of the present disclosure, the flange body 102 may have fewer or additional recesses and fluid channels in other examples and remain within the scope of the disclosure.

With continuing reference to FIG. 3, the injection flange assembly 100 may include a plurality of fluid supply headers 192, for example a first fluid supply header 192A and a second fluid supply header 192B. In the illustrated example the first fluid supply header 192A couples (e.g., fluidly couples) the first fluid source 306 to the flange body 102 through the first fluid conduit 114 through the first MFC device 122. As shown and described herein the first fluid supply header 192A also couples the first fluid source 306 to the flange body 102 through the third fluid conduit 118 and the third MFC device 126. It is contemplated that the second fluid supply header 192B couples (e.g., fluidly couple) the second fluid source 308 to the flange body 102 through the second fluid conduit 116 and the second MFC device 124, the second fluid conduit 116 in turn coupled to the flange body 102 through union 120. It is further contemplated that the union 120 be arranged along the first fluid conduit 114, the union 120 in turn coupling (e.g., fluidly coupling) both the first MFC device 122 and the second MFC device 124 to the flange body 102. In certain examples, the first fluid source 306 may communicate the silicon-containing material layer precursor 314 to the flange body lateral slit 136 intermixed with the dopant-containing material layer precursor 318 from both (a) the second fluid source 308 (e.g., through the union 120) and (b) the third fluid conduit 118. As will be appreciated by those of skill in the art in view of the present disclosure, communicating the dopant-containing material layer precursor 318 through only the third MFC device 126 while communicating the silicon-containing material layer precursor 314 enables controlling cross-substrate dopant concentration with limited (or substantially) no crosstalk into the cross-substrate material layer thickness profile.

In certain examples the third fluid source 310 may be coupled to the flange body 102 through either (or both) the first fluid supply header 192A and the second fluid supply header 192B. In this respect it is contemplated the third fluid source 310 may communicate the etchant-containing fluid 322 to the flange body lateral slit 136. Communication of the etchant-containing fluid 322 to the flange body lateral slit 136 may be through one or more of the first fluid conduit 114, the second fluid conduit 116, and the third fluid conduit 118. Communication of the etchant-containing fluid 322 to the flange body lateral slit 136 may further be through the first fluid channel 188A and the second fluid channel 188B, and therethrough via the first recess 186A and the second recess 186B. As will be appreciated by those of skill in the art in view of the present disclosure, communicating the etchant-containing fluid 322 to the flange body lateral slit 136 enables introducing the etchant-containing fluid 322 into the interior 420 (shown in FIG. 2) of the chamber body 406 (shown in FIG. 2) to selectively deposit the material layer 12 onto the substrate 10 and/or etch structures within the chamber body 406.

In certain examples the fourth fluid source 312 may be coupled to the flange body 102 through either (or both) the first fluid supply header 192A and the second fluid supply header 192B such that the fourth fluid source 312 may communicate the carrier/purge fluid 324 to the flange body lateral slit 136. In this respect it is contemplated that the carrier/purge fluid 324 may be communicated to the flange body lateral slit 136 intermixed with either (or both) the silicon-containing material layer precursor 314 and the dopant-containing material layer precursor 318. In further respect, it is also contemplated that the carrier/purge fluid 324 may be communicated to the flange body lateral slit 136 intermixed with the etchant-containing fluid 322 or independent of one or more of the aforementioned process fluids. As will be appreciated by those of skill in the art in view of the present disclosure, communicating the carrier/purge fluid 324 into the flange body lateral slit 136 intermixed with either (or both) the silicon-containing material layer precursor 314 and/or the dopant-containing material layer precursor 318 enables control of mass flow rate independent of fluid volume communicated to the interior 420 of the chamber body 406 as well as enabling purge of the interior 420 of the chamber body 406 using the carrier/purge fluid 324, as appropriate for the mode of the semiconductor processing system 200 (shown in FIG. 1).

In certain examples the first fluid conduit 114 may be one of a plurality of first fluid conduits 114, the second fluid conduit 116 may be one of a plurality of second fluid conduits 116, and the third fluid conduit 118 may be one of a plurality of third fluid conduits 118. In such examples the plurality of first fluid conduits 114 may couple the first fluid supply header 192A to the flange body 102, the plurality of second fluid conduits 116 may couple the second fluid supply header 192B to the flange body 102 through respective ones of a plurality of unions 120 each arranged along individual ones of the plurality of first fluid conduits 114, and the plurality of third fluid conduits 118 may coupling the second fluid supply header 192B to the flange body 102. In such examples the first MFC device 122 may be one of a plurality of first MFC devices 122, the second MFC device may be one of a plurality of second MFC devices 124, and the third MFC device may be one of a plurality of third MFC devices 126. Individual ones of the plurality of first MFC devices 122 may be arranged along each of the plurality of first fluid conduits 114, individual ones of the plurality of second MFC devices 124 may be arranged along each of the plurality of second fluid conduits 116, and individual ones of the plurality of third MFC devices 126 may be arranged along each of the plurality of third fluid conduits 118.

In the illustrated example the injection flange assembly 100 includes four (4) first fluid conduits 114 and three (3) third fluid conduits 118 each coupling the first fluid source 306 to the flange body 102 through the second fluid supply header 192B. As will be appreciated by those of skill in the art in view of the present disclosure, this provides cross-substrate material layer thickness tunability (e.g., cross-substrate thickness uniformity of the material layer 12) using the plurality of first MFC devices 122 and third MFC devices 126 in cooperation with lateral spacing and/or geometry of the plurality of recesses 186 defined within the first face 130 of the flange body 102 through lateral mass flow rate throttling of the silicon-containing material layer precursor 314 at introduction into the flange body lateral slit 136. In the illustrated example the injection flange assembly 100 also includes three (3) second fluid conduits 116 each coupling the second fluid source 308 to the flange body 102 through the first fluid supply header 192A. As will also be appreciated by those of skill in the art in view of the present disclosure, this provides cross-substrate dopant concentration (e.g., for uniformity independent of thickness uniformity of the material layer 12) using the plurality of second MFC devices 124 also in cooperation with lateral spacing and/or geometry of the subset of the plurality of recesses 186 defined within the first face 130 of the flange body 102 through lateral mass flow rate throttling of the dopant-containing material layer precursor 318 at introduction into the flange body lateral slit 136. Although shown and described herein as having specific number of first fluid conduits 114, second fluid conduits 116, and third fluid conduits 118, it is to be understood and appreciated that the injection flange assembly 100 may have fewer or additional first fluid conduits 114, second fluid conduits 116, and/or third fluid conduits 118 in other examples and remain within the scope of the disclosure.

Referring to FIG. 9, the recess 186 may be generally triangular in shape. In this respect it is contemplated that the recess 186 may define a triangular profile 194. The triangular profile 194 may extend longitudinally within the flange body 102 and in a general direction of flow of the process fluid 302 (shown in FIG. 1) and in a general direction opposite the flow of the process fluid 302 within the chamber arrangement 400 (shown in FIG. 1) between the process fluid supply conduit 304 (shown in FIG. 1) and the exhaust conduit 502 (shown in FIG. 1). In this respect it is contemplated that the triangular profile 194 may be offset from the second face 132 of the flange body 102 and bounded (in part) by the first face 130 of the flange body 102. In further respect, the triangular profile 194 may be substantially orthogonal relative to the first face 130 and the second face 132 of the flange body 102. In the illustrated example the recess 186 is one of a plurality of recesses 186 distributed laterally within the flange body 102, for example between first lateral edge 148 and the second lateral edge 150 of the flange body 102. Although shown and described herein as having seven (7) recesses 186 it is to be understood and appreciated that the flange body 102 may have fewer or additional recesses 186 and remain within the scope of the present disclosure.

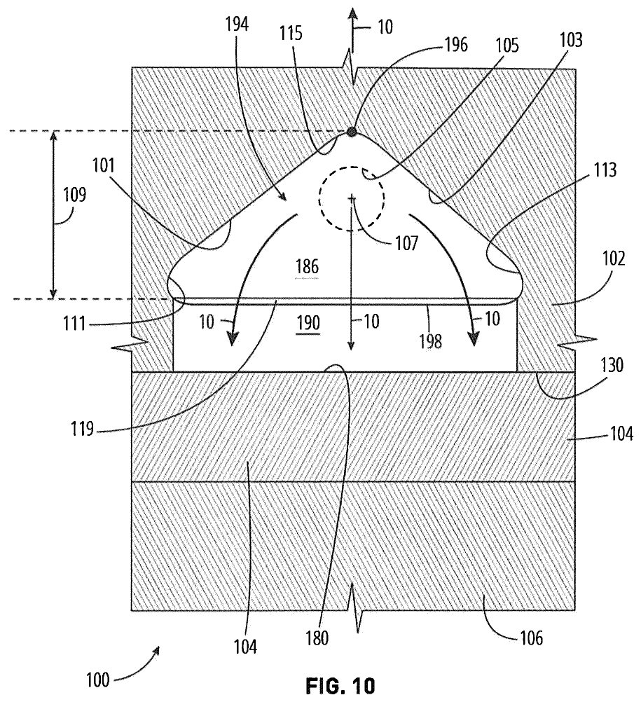

As shown in FIG. 10, it is contemplated that the triangular profile 194 defined by the recess 186 have a vertex 196, base segment 198, a first leg segment 101, and a second leg segment 103. It is contemplated that the vertex 196 be located within the thickness 158 (shown in FIG. 4) of the flange body 102 and proximate the second face 132 (shown in FIG. 5) of the flange body 102, that the base segment 198 of the triangular profile 194 be longitudinally opposite the vertex 196 of the triangular profile 194, and that the base segment 198 of the triangular profile 194 be proximate the first face 130 of the flange body 102. In this respect the base segment may be separated from the second face 156 of the plate body 104 by the injection port 190, the injection port 190 in turn defined between the first face 130 of the flange body 102 and the second face 156 of the plate body 104.

The first leg segment 101 of the triangular profile 194 may extend between the base segment 198 and the vertex 196. The first leg segment 101 may further be oblique relative to the first face 130 and the second face 132 of the flange body 102. The second leg segment 103 of the triangular profile 194 may also extend between the base segment 198 of the triangular profile 194, may also be oblique to the first face 130 and the second face 132 of the flange body 102, and further be laterally offset from the first leg segment 101 of the triangular profile 194 within the thickness 158 (shown in FIG. 4) of the flange body 102.

It is contemplated that the fluid channel 188 (shown in FIG. 5) fluidly communicate with the recess 186 through a fluid channel outlet 105. The fluid channel outlet 105 may in turn be located along a flow axis 107 defined by the fluid channel 188, may extend about the flow axis 107, and overlay the triangular profile 194 of the recess 186. The fluid channel outlet 105 may further be located longitudinally between the vertex 196 and the base segment 198 of the triangular profile 194, for example at a location longitudinally intermediate the vertex 196 and the base segment 198 of the triangular profile 194. In certain examples the fluid channel outlet 105 may be longitudinally offset from the vertex 196 of the triangular profile 194. In accordance with certain examples, the fluid channel outlet 105 may be longitudinally offset from the base segment 198 of the triangular profile 194. It is also contemplated that the fluid channel outlet 105 may couple the fluid channel 188 to the recess 185 at a location within the thickness 158 of the flange body 102 longitudinally intermediate both the vertex 196 and the base segment 198 to the triangular profile 194.

In certain examples the fluid channel outlet 105 may be between about 10% and about 90% of a height 109 of the triangular profile 194. In accordance with certain examples, the fluid channel outlet 105 may be between about 30% and about 60% of the height 109 of the triangular profile 194. It is also contemplated that the fluid channel outlet 105 may be between about 30% and about 50% of the height 109 of the triangular profile 194. Advantageously, such relationship between position of the fluid channel outlet 105 and shape of the recess 186 may promote lateral uniformity in velocity of fluid issued from the recess 186 through the injection port 190, for example within an aggregate mass flow adjustment range of the first MFC device 122 and the second MFC device 124. As will be appreciated by those of skill in the art in view of the present disclosure, lateral uniformity in velocity of fluid issued from the injection port 190 may promote laminar flow within the interior 420 (shown in FIG. 2) of the chamber body 406 (shown in FIG. 2), limiting cross-substrate variation within the material layer 12 deposited onto the substrate 10 using the fluid communicated to the chamber arrangement 400 (shown in FIG. 1) otherwise associated non-laminar flow within the interior 420 of the chamber body 406.

In certain examples the recess 186 may be bounded by one or more arcuate surface. In this respect the base segment 198 of the triangular profile 194 defined by the recess 186 may be coupled to the first leg segment 101 of the triangular profile 194 by a first base-to-leg arcuate segment 111. The base segment 198 may be coupled to the second leg segment 103 by a second base-to-leg arcuate segment 113. It is contemplated that the first leg segment 101 of the triangular profile 194 may be coupled to the second leg segment 103 by a vertex arcuate segment 115. It is contemplated that fluid channel 188 may join the recess 186 at an arcuate surface, for example at a fluid channel outlet chamfer 117 (shown in FIG. 8) extending about the flow axis 107 and joining the fluid channel outlet 105 to an upper interior surface of the flange body 102 bounding the recess 186. It is also contemplated that the recess 186 may join the injection port 190 at a recess-to-injection port arcuate surface 119. The recess-to-injection port arcuate surface 119 may join an interior surface of the flange body 102 bounding the recess 186 to flange body lateral slit 136. Advantageously, such arcuate surfaces may limit (or eliminate) where surfaces bounding the recess 186 join one another edge features, reducing or preventing entirely turbulence and/or localized recirculation zones that could otherwise develop within fluid flow within the recess 186 due to such edge features. As will be appreciated by those of skill in the art in view of the present disclosure, limiting (or eliminating) turbulence and localized recirculation zones within the fluid traversing the recess 186 may also promote lateral uniformity in velocity of fluid issued from the injection port 190 may promote laminar flow within the interior 420 (shown in FIG. 2) of the chamber body 406 (shown in FIG. 2), further limiting cross-substrate variation within the material layer 12 deposited onto the substrate 10 using the fluid communicated to the chamber arrangement 400 (shown in FIG. 1) otherwise associated non-laminar flow within the interior 420 of the chamber body 406.

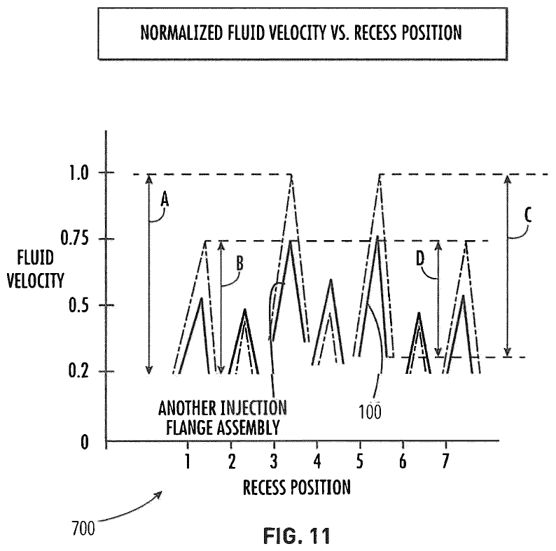

With reference to FIG. 11, a chart 700 comparatively showing lateral variation of fluid issue velocity from the first injection flange assembly 100 (shown in FIG. 1) relative to another injection flange assembly, for example an injection flange assembly having a displaced and/or distorted plate body as well as one or more non-triangular recess, is shown. As shown comparatively with a cross-assembly velocity distribution A and a cross-flange velocity distribution B, the injection flange assembly 100 may exhibit 40% less variation in fluid velocity issued from the injection flange assembly 100 in comparison to other injection flange assemblies. As shown comparatively with a cross-injection port velocity distribution C and a cross-injection port velocity distribution D, the injection flange assembly 100 may exhibit some 40% less fluid velocity variation in fluid issued from an individual injection port. As will be appreciated by those of skill in the art in view of the present disclosure, the relatively low variation in fluid velocity of fluid issued from the injection flange assembly 100 may promote laminar flow of the fluid within the chamber arrangement 400, limiting either (or both) cross-substrate material layer thickness variation in the material layer 12 deposited onto the substrate 10 and/or cross-substrate dopant concentration variation within the material layer 12.

In certain examples, one or more of the fasteners configured to compressively fix the plate body to the flange body, e.g., the fastener 108 shown in FIG. 4, and/or one or more of the threaded members configured to carry load of the gate valve directly through the flange body, e.g., the threaded member 110 shown in FIG. 8, may be formed from a nickel-base superalloy material to improve preload retention under cyclic thermal conditions. Non-limiting examples of suitable nickel-base superalloys include Inconel® 625, Inconel® 718, and equivalents. Advantageously, nickel-base superalloy fasteners exhibit enhanced high-temperature strength and reduced stress relaxation relative to austenitic stainless steel fasteners (e.g., 316 stainless), thereby maintaining clamping force on the plate body 104 and limiting formation of micro-gaps at interfaces that could otherwise introduce instability in flow issued through one or more injection port 190.

It is contemplated that, when nickel-base superalloy fasteners are employed, a predetermined fastener preload may be selected to account for the higher high-temperature strength and relaxation resistance of the fastener material. In certain examples, the predetermined fastener preload value 135 may be achieved by tightening each of the plurality of fasteners 108 to a target torque that is greater than a baseline torque suitable for austenitic stainless steel fasteners. In accordance with certain examples, the plurality of fasteners 108 may be tightened to a target torque of about 4.0 newton-meters (Nm), for example within a range between about 3.0 Nm and about 4.0 Nm, whereas a baseline torque of about 2.0 Nm may be suitable for 316 stainless steel fasteners. As will be appreciated by those of skill in the art in view of the present disclosure, the specific torque values may be adjusted based on fastener size, thread pitch, surface finish, coating and/or lubrication condition, and are therefore presented as non-limiting examples.

In certain examples, the predetermined fastener tightening sequence 133 may be implemented as a staged crosswise (e.g., star-pattern) sequence to equalize clamping load around the bolt circle and draw the plate body 104 into full, uniform contact with the first face 130 of the flange body 102. In one example, the plurality of fasteners 108 are tightened in three stages at approximately 30%, 60%, and 100% of the target torque, repeating the crosswise sequence at each stage. Advantageously, staged crosswise tightening limits plate body distortion during assembly, promotes uniform compression of any seal member 153 seated about the flange body lateral slit 136, and reduces lateral variation in velocity of fluid issued from the plurality of injection ports 190.

It is further contemplated that substituting nickel-base superalloy for the material of the threaded member 110 may similarly improve retention of the predetermined threaded member preload 139 under thermal cycling, limiting the tendency of the gate valve 106 to impart a bending moment onto the plate body 104 through relaxation of the threaded member 110. In certain examples, the threaded member 110 formed from a nickel-base superalloy may be tightened to a predetermined preload selected to maintain clamp force on the flange portion 184 of the gate valve body 172 while preserving the clearance within the through-hole 162 to avoid reaction forces on the plate body 104. As will be appreciated, maintaining clamp force during operation promotes stability of the lateral fluid velocity profile by preserving the geometry of the injection ports 190 defined between the plate body 104 and the flange body 102.

In certain examples, implementing nickel-base superalloy fasteners and threaded members as described herein, in combination with the predetermined fastener tightening sequence 133 and the predetermined fastener preload value 135, may reduce or eliminate inter-pocket leakage and flow crosstalk otherwise caused by incomplete contact between the plate body 104 and the flange body 102. Advantageously, improved contact uniformity at the mating interfaces limits localized recirculation and turbulence in the recesses 186, thereby promoting laminar flow through the injection ports 190 and reducing wafer-to-wafer and point-to-point variation of both material layer thickness and sheet resistance (Rs) in semiconductor processing systems.

In certain examples, the substitution of nickel-base superalloy fasteners for austenitic stainless steel fasteners may be implemented without modifying the geometry of the plate body fastener apertures 160 or the first threaded apertures 166, for example when the fastener size and thread specification remain unchanged. In such examples, the head portion seat 131 defined within the plate body 104 may continue to recess the head of the fastener 108 below the first face 154 of the plate body 104 to enable flush mounting of the gate valve 106, while the enhanced high-temperature strength of the fastener material maintains clamping force after repeated thermal cycles.

Although particular nickel-base superalloys are identified herein, it is contemplated that other high-temperature fastener materials exhibiting comparable high-temperature yield strength, creep resistance, and relaxation behavior may be employed in lieu of austenitic stainless steel to achieve substantially similar benefits. Suitable alternatives may include precipitation-hardened stainless steels and other nickel-chromium-molybdenum alloys, provided that contamination risk to the substrate 10 and material layer 12 remains acceptable for the intended semiconductor process conditions.

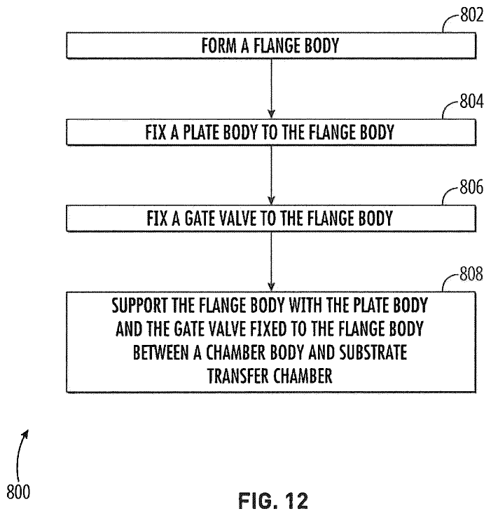

With reference to FIG. 12 to FIG. 14, a method 800 of making an injection flange assembly, e.g., the injection flange assembly 100 (shown in FIG. 1), is shown. As shown in FIG. 12, the method 800 may include forming a flange body, e.g., the flange body 102 (shown in FIG. 3), as shown with box 802. The method 800 also includes fixing a plate body, e.g., the plate body 104 (shown in FIG. 3), to the flange body, as shown with box 804. The method 800 additionally includes fixing a gate valve, e.g., the gate valve 106 (shown in FIG. 3), to the flange body, as shown with box 806. It is further contemplated that the method 800 may include coupling a chamber arrangement for a semiconductor processing system to a substrate transfer module of the semiconductor processing system, e.g., coupling the chamber arrangement 400 (shown in FIG. 1) to the substrate transfer module 204 (shown in FIG. 2), as shown with box 808. Although shown and described herein as including certain operations and a specific order, it is to be understood and appreciated that the method 800 may include additional operations and/or exclude certain operations shown and described herein, and/or that operations shown and described herein be performed in an order differing from that shown and described herein, and remain within the scope of the present disclosure.

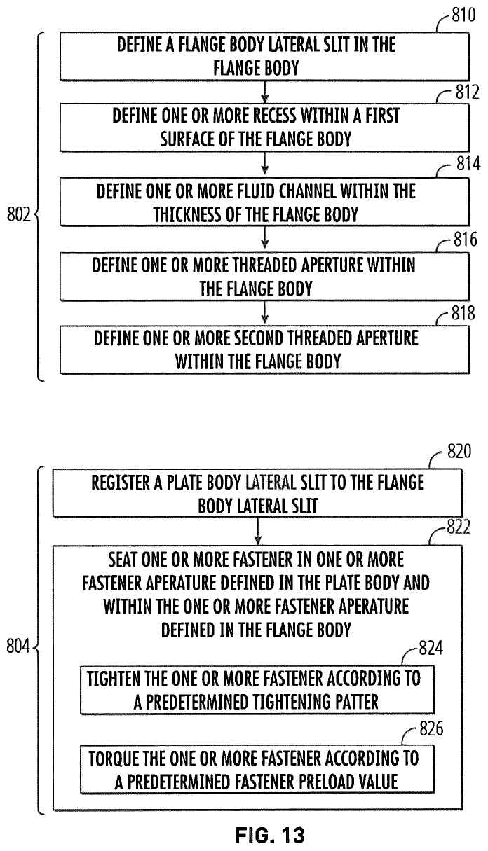

As shown in FIG. 13, forming 802 the flange body may include defining a flange body lateral slit within the flange body, e.g., the flange body lateral slit 136 (shown in FIG. 4), as shown with box 810. Forming 802 the flange body may include defining one or more recess within the first face of the flange body, e.g., the recess 186, as shown with box 812. Forming 802 the flange body may include defining one or more fluid channel within a thickness of the flange body, e.g., the fluid channel 188 (shown in FIG. 5), as shown with box 814. Forming 802 the flange body may include defining one or more first threaded aperture within a first face of the flange body, e.g., the first threaded aperture 166 (shown in FIG. 5) in the first face 130 (shown in FIG. 5) of the flange body, as shown with box 816. Forming 802 the flange body may include forming one or more second threaded aperture within the first face of the flange, e.g., the second threaded aperture 168 (shown in FIG. 4), as shown with box 818. In certain examples forming 802 the flange body may include forming the flange body from a flange body material, e.g., the flange body material 128 (shown in FIG. 8), as shown with box 810. In such examples the metallic material may include a low-copper content metallic material, such as a low-copper content metallic material having a relatively high coefficient of heat transfer, as also shown with box 810. It is contemplated that one or more of the aforementioned features may be defined in the flange body using a subtractive manufacturing process, such as milling and/or drilling, and/or an additive manufacturing technique, such as powder bed fusion technique, as further shown with bracket 802.

Fixing 804 the plate body to the flange body may include forming the plate body, as shown with bracket 804. Forming the plate body may include defining a plate body lateral slit in the plate body, e.g., the plate body lateral slit 164 (shown in FIG. 6), as also shown with bracket 804. Forming 820 the plate body may include defining one or more fastener aperture in the plate body, e.g., the plate body fastener aperture 160 (shown in FIG. 6), as shown with box 804. Forming 820 the plate body may include defining one or more though-hole in the plate body, e.g., the through-hole 162 (shown in FIG. 6), as shown with box 804. Fixing 804 the plate body to the flange body may include registering the plate body to the flange body, as shown with box 820. In this respect it is contemplated registering 820 the plate body to the flange body may include registering the plate body lateral slit to the flange body, as also shown with box 820. Registering 820 the plate body to the flange body may include registering the one or more plate body fastener aperture to the one or more first threaded aperture defined within the first face of the flange body, as further shown with box 820. It is further contemplated that registering 824 the plate body to the flange body may include registering the one or more through-hole defined in the plate body to the one or more second threaded aperture defined in the first face of the plate body, as additionally shown with box 820. It contemplated that registration may be accomplished using a plate body seat defined within the first face of the flange body, e.g., the plate body seat 144 (shown in FIG. 5), which may simplify assembly of the injection flange assembly. It is contemplated that one or more of the aforementioned features may be defined in the plate body using a subtractive manufacturing process, such as milling and/or drilling, and/or an additive manufacturing technique, such as powder bed fusion technique, as further shown with box 820. It is also contemplated that Forming 820 the plate body may include forming the plate body from a material differing from that of the flange body and/or the gate valve body, for example having a lower coefficient of heat transfer than the flange body, as also shown 820. Advantageously, this can cause the plate body to operate as a thermal break or a thermal choke, limiting need to otherwise cool the gate valve during operation.

In certain examples Fixing 804 the plate body to the flange body may include fixing the plate body to the flange body with a plurality of fasteners by threadedly seating each within a respective one of the plurality of first threaded apertures, as shown which box 822. In such examples the fasteners may be tightened according to a predetermined fastener tightening pattern or sequence, e.g., the predetermined fastener tightening sequence 133 (shown in FIG. 3), as shown with box 824. Advantageously, tightening the plurality of fasteners according to the predetermined fastener tightening pattern may promote uniformity in fluid velocity of fluid issued from one or more injection port bounded by the first face of the flange body and the plate body, e.g., the injection port 190 (shown in FIG. 8), for example by limiting (or preventing entirely) deformation of the plate body during fixation of the plate body onto the flange body. In accordance with certain examples, one or more of the plurality of fasteners may be tightened to impart of predetermined preload into the one or more plurality of fasteners, e.g., the predetermined fastener preload value 135 (shown in FIG. 3), as shown with box 826. Advantageously, imparting a predetermined fastener preload into the one or more fastener (or all of the plurality of fasteners) may limit tendency of the plate body to displace and/or distort relative to the flange body, as due to heating and/or mismatch in the coefficient of heat transfer of differing materials forming the plate body and the flange body. As will be appreciated by those of skill in the art in view of the present disclosure, limiting displacement and/or distortion of the plate body may in turn promote stability in the lateral fluid velocity profile of fluid issued from the injection flange assembly during service, for example in operating regimes where the injection flange assembly is cyclically heated and cooled during sequential cycles of substrate loading, material layer deposition onto the substrate, and subsequent unloading of the substrate from a semiconductor processing system.

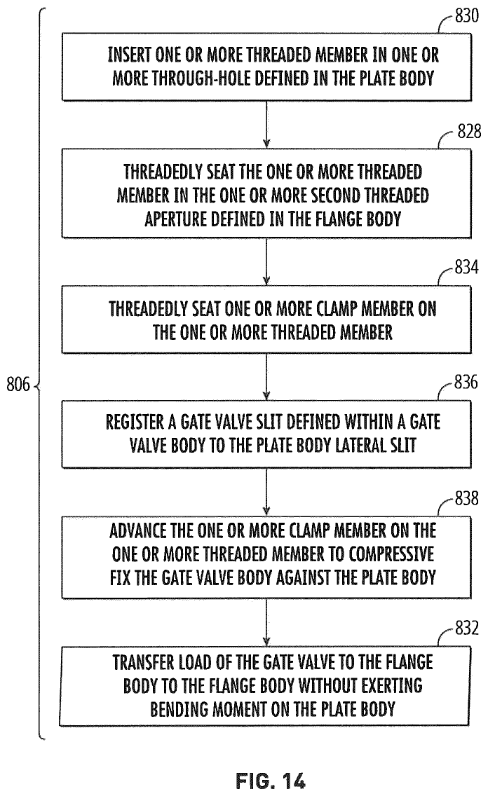

As shown in FIG. 14, fixing 806 the gate valve to the flange body may include seating one or more threaded member within the flange body, e.g., the threaded member 110 (shown in FIG. 8), as shown with box 828. In certain examples seating 832 the one or more threaded member in the flange body may include seating a plurality of threaded members in the flange body, as also shown with box 828. The one or more threaded member may be slidably received within the through-hole defined within the plate body and threadedly fixed within the one or more second threaded aperture defined in flange body, as shown with box 830. It is contemplated that the one or more threaded member may be received within the through-hole such that, when loaded with a bending moment, substantially no force component associated with the bending moment is exerted on the plate body, as also shown with box 832. For example, the through-hole may be oversized relative to the threaded member such that, when threadedly fixed in the flange body, the threaded member is spaced apart from the plate body within the through-hole, for example by a clearance. It is further contemplated seating 828 the one or more threaded member within the plate body may include imparting a predetermined threaded member preload into the threaded member, e.g., the predetermined threaded member preload 139 (shown in FIG. 8), as also shown with box 828. Advantageously, imparting the predetermined preload into the one or more threaded member may limit deformation (e.g., bending) of the threaded member a bending moment is exerted on the threaded member, limiting (or eliminating) tendency of such a bending moment to exert a bending moment on the plate body. As will be appreciated by those of skill in the art of the present disclosure, this may limit variation potentially introduced into lateral flow velocity of fluid issued from the injection flange assembly otherwise potentially associated with deformation of the plate body by such a bending moment.

It is contemplated that fixing 806 the gate valve to the flange body may include threadedly seating one or more clamp member to the one or more threaded member, e.g., the one or more clamp member 112 (shown in FIG. 8), as shown with box 834. Fixing 806 the gate valve to the flange body may further include registering a gate valve lateral slit at the flange body lateral slit, e.g., the gate valve lateral slit 182 (shown in FIG. 7), as shown with box 836. In this respect is contemplated that a flange portion of a gate valve body may be interposed between the clamp member and the plate body, e.g., the flange portion 184 (shown in FIG. 7) of the gate valve body 172 (shown in FIG. 7), as also shown with box 836. It is contemplated that the clamp member may thereafter be advanced relative to the flange body (e.g., by tightening the one or more threaded member within the second threaded aperture defined in the flange body) such that the gate valve is compressively fixed between the clamp member and the flange body, for example by imparting a tensile load into the threaded member, such that load of the gate valve is carried directly by the flange body through the threaded member and without exerting the load on the plate body, as further shown with box 838.

In certain examples seating 828 the one or more threaded member in the flange body may include tightening a plurality of threaded members according to a predetermined threaded member tightening sequence, e.g., the predetermined threaded member tightening sequence 137 (shown in FIG. 3), as further shown with box 828. It is contemplated that the predetermined threaded member tightening sequence may be selected to limit deformation of the flange body otherwise associated with tightening the plurality of threaded members, as also shown with box 828. Advantageously, limiting deformation of the flange body otherwise potentially associated with sequence in which the plurality of threaded members are tightened may limit variation associated with such deformation into lateral flow velocity of fluid issued by the injection flange assembly, for example due to the deformation altering shape of one or more of the injection ports defined by the flange body and the plate body of the injection assembly.

With reference to FIG. 15, a method 900 of controlling fluid flow is shown. The method 900 includes communicating a fluid to a flow channel defined within a flange body of an injection flange assembly, e.g., the process fluid 302 (shown in FIG. 1) to the fluid channel 188 (shown in FIG. 8) defined within the flange body 102 (shown in FIG. 3) of the injection flange assembly 100 (shown in FIG. 1), as shown with box 902. The method 900 also includes flowing the process fluid to a recess defined within a first face of the flange body from the fluid channel, e.g., the recess 186 (shown in FIG. 4) defined in the first face 130 (shown in FIG. 4) of the flange body, as shown with box 904. The method 900 further includes issuing the process fluid into a flange body lateral slit extending through a thickness of the flange body and coupling the first face of the flange body to a second face of the flange body, e.g., the flange body lateral slit 136 (shown in FIG. 4), as shown with box 906. It is contemplated that lateral variation of flow velocity of the process fluid be limited using the injection flange assembly, as shown with box 908. In this respect it is contemplated that a first fluid may be intermixed with a second fluid external to the injection flange assembly, as shown with box 910. In further respect, the recess may shaped and dimensioned to limit turbulence and recirculation therein, for example having arcuate or rounded sidewalls and increasing in lateral width from the second face to the first face of the flange body, owing to process fluid mixing that occurs outside of the flange body and within the fluid channel prior to arrival at the recess, as also shown with box 904.

In certain examples intermixing 910 the first fluid with the second fluid may include intermixing a silicon-containing material layer precursor with a dopant-containing material layer precursor outside of the injection flange body, e.g., the silicon-containing material layer precursor 314 (shown in FIG. 3) with the dopant-containing material layer precursor 318 (shown in FIG. 3), as shown with box 910. The silicon-containing material layer precursor and the dopant-containing material layer precursor may be intermixed outside of the flange body and thereafter communicated to the fluid channel, as also shown with box 910. It is contemplated that a material layer may be deposited onto a substrate using the process fluid, e.g., the material layer 12 (shown in FIG. 1) onto the substrate 10 (shown in FIG. 1), as shown with box 912. The material layer may be a dopant-containing silicon material layer deposited onto a semiconductor substrate using an epitaxial technique, as also shown with box 912, and variation of at least one of cross-substrate thickness and cross-substrate dopant concentration may be limited using lateral variation in fluid velocity of the process fluid issued from the recess, as further shown with box 908.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

What is claimed:

1. An injection flange assembly, comprising:
a flange body having:
a first face with a recess defined therein; and
a second face separated from the first face by a thickness of the flange body,
wherein the first face is coupled to the second face by a flange body lateral slit extending through the thickness of the flange body,
wherein the flange body defines a fluid channel within the thickness of the flange body fluidly coupling the recess to an edge of the flange body, the edge coupling a first face of the flange body to a second face of the flange body, and
wherein the first face of the flange body defines therein a first threaded aperture and a second threaded aperture, the first threaded aperture separating the edge from the second threaded aperture, the second threaded aperture separating the first threaded aperture from the recess, and the recess fluidly coupling the fluid channel to the flange body lateral slit extending through the thickness of the flange body.

2. The injection flange assembly of claim 1, further comprising:
a fluid conduit coupled to the edge of the flange body; and
a union coupled to the fluid conduit and in fluid communication therethrough with the flange body lateral slit through the fluid channel and the recess defined within the first face of the flange body.

3. The injection flange assembly of claim 2, further comprising:
a first mass flow controller device coupled to the union; and
a second mass flow controller device coupled to the union,
wherein the union is configured to intermix a first fluid provided by the first mass flow controller device with a second fluid provided by the second mass flow controller device prior to communication to the recess defined in the first face of the flange body.

4. The injection flange assembly of claim 2, further comprising:
a first fluid source coupled to the union and configured to communicate a first fluid to the union; and
a second fluid source coupled to the union and configured to communicate a second fluid to the union,
wherein the union is configured to intermix the second fluid with the first fluid prior to communication of the first fluid and the second fluid to the recess defined in the first face of the flange body.

5. The injection flange assembly of claim 1, further comprising:
a plate body abutting the first face of the flange body, the plate body extending about the flange body lateral slit coupling the first face to the second face of the flange body; and
a fastener extending through the plate body and threadedly seated in the first threaded aperture, the fastener compressively fixing the plate body to the first face of the flange body.

6. The injection flange assembly of claim 5, wherein the first threaded aperture is one of a plurality of first threaded apertures distributed laterally on the first face of the flange body, wherein the fastener is one of a plurality of fasteners, and wherein the plurality of fasteners are each seated in an individual one of the plurality of first threaded apertures defined within the first face of the flange body to compressively fix the plate body to the first face of the flange body.

7. The injection flange assembly of claim 5, wherein the second threaded aperture is one of a plurality of second threaded apertures, wherein a threaded member is one of a plurality of threaded members, and wherein the plurality of threaded members are each seated in individual ones of the plurality of second threaded apertures.

8. The injection flange assembly of claim 1, wherein the recess has a triangular profile, the triangular profile comprising:
a vertex proximate the second face of the flange body;
a base segment proximate the first face of the flange body; and
a first leg segment and a second leg segment both coupling the base segment of the triangular profile to the vertex of the triangular profile.

9. The injection flange assembly of claim 8, wherein the fluid channel intersects the recess at a fluid channel outlet, wherein the fluid channel outlet is offset from the vertex of the triangular profile defined by the recess, and wherein the fluid channel outlet is offset from the base segment of the triangular profile defined by the recess.

10. The injection flange assembly of claim 8, wherein the triangular profile further comprises:
a vertex arcuate segment coupling the first leg segment to the second leg segment;
a first base-to-leg arcuate segment coupling the base segment to the first leg segment of the triangular profile defined by the recess; and
a second base-to-leg arcuate segment coupling the base segment to the second leg segment of the triangular profile defined by the recess.

11. The injection flange assembly of claim 1, wherein the recess is one of a plurality of recesses distributed laterally between a first side and a laterally opposite second side of the flange body.

12. The injection flange assembly of claim 1, wherein there are no recesses defined in the second face of the flange body between the flange body lateral slit and the edge of the flange body, the second face continuous and uninterrupted in contour between the flange body lateral slit and the edge of the flange body.

13. The injection flange assembly of claim 1, further comprising:
a threaded member seated in the second threaded aperture; and
a gate valve depending from the threaded member and cantilevered directly therethrough by the flange body.

14. A chamber arrangement, comprising:
a chamber body having an injection end and an exhaust end, the exhaust end of the chamber body longitudinally opposite the injection end of the chamber body;
a substrate support supported within the chamber body for rotation about a rotation axis between the injection end and the exhaust end of the chamber body;
the injection flange assembly as recited in claim 1 abutting the injection end of the chamber body, the injection flange assembly further comprising:
a plate body abutting the first face of the flange body and extending about the flange body lateral slit extending through the thickness of the flange body;
a fastener extending through the plate body and seated in the first threaded aperture, the fastener compressively fixing the plate body to a first face of the plate body;
a threaded member extending through the plate body and seated in the second threaded aperture; and
a gate valve depending from the threaded member and carried directly therethrough by the flange body.

15. A semiconductor processing system, comprising:
a chamber body having an injection end and a longitudinally opposite exhaust end;
a substrate support arranged within an interior of the chamber body;
the injection flange assembly as recited in claim 1 abutting the injection end of the chamber body and separated from the exhaust end of the chamber body by the substrate support;
a process fluid source with a process fluid and coupled to the injection flange assembly; and
a controller operatively connected to the process fluid source and responsive to instructions recorded on a memory to:
communicate the process fluid to the fluid channel using the process fluid source;
flow the process fluid to the recess through the fluid channel; and
issue the process fluid into the flange body lateral slit from the recess to deposit a material layer onto a substrate seated on the substrate support using the process fluid.

16. A method of making an injection flange assembly, comprising:
forming a flange body by:
defining a flange body lateral slit in the flange body, the flange body lateral slit extending through a thickness of the flange body, the flange body lateral slit coupling a first face of the flange body to a second face of the flange body, the second face of the flange body separated from the first face of the flange body by the thickness of the flange body;
defining a recess in the first face of the flange body;
defining a first threaded aperture in the first face of the flange body;
defining a second threaded aperture in the first face of the flange body at a location whereat the first threaded aperture separates an edge of the flange body from the second threaded aperture and the second threaded aperture separates the first threaded aperture from the recess; and
defining a fluid channel within the thickness of the flange body, the fluid channel coupling the edge of the flange body to the recess defined in the first face of the flange body, the edge coupling the first face of the flange body to the second face of the flange body,
whereby the recess fluidly couples the fluid channel to the flange body lateral slit extending through the thickness of the flange body.

17. The method of claim 16, further comprising:
coupling a first fluid conduit with a union arranged therealong to the edge of the flange body such that the first fluid conduit is fluidly coupled to the fluid channel; and
coupling a second fluid conduit to the union, the second fluid conduit thereby being fluidly coupled to the fluid channel.

18. The method of claim 16, wherein defining the recess further comprises defining the recess with a triangular profile, the triangular profile having a vertex proximate the second face of the flange body, the triangular profile having a base segment proximate the first face of the flange body.

19. The method of claim 16, further comprising fixing a plate body to the flange body having a plate body lateral slit extending therethrough, a fastener aperture extending through the plate body, a through-hole extending through the plate body; fixing the plate body to the flange body comprising:
registering the plate body lateral slit to the flange body lateral slit, whereby the fastener aperture is registered to the first threaded aperture and the through-hole is registered to the second threaded aperture; and
threadedly seating a fastener in the first threaded aperture defined within the first face of the flange body and through the fastener aperture.

20. The method of claim 19, further comprising fixing a gate valve to the flange body, the gate valve including a gate valve body defining a gate valve lateral slit therethrough, fixing the gate valve to the flange body comprising:
inserting a threaded member in the through-hole defined in the plate body;
threadedly seating the threaded member in the second threaded aperture of the flange body;
threadedly seating a clamp member on the threaded member;
registering the gate valve lateral slit to the flange body lateral slit; and
advancing the threaded member into the second threaded aperture such that the clamp member compressively fixes the gate valve against the plate body and the load of the gate valve is carried directly by the flange body.
